(19) United States
(12) Patent Application Publication
(10) Pub. No.: US 2008/0191724 A1
(43) Pub. Date: Aug. 14, 2008

(54) Electrical testing device for testing electrical test samples

(75) Inventors: Georg Steidle, Waldenbuch (DE); Gunther Bohm, Nufringen (DE)

Correspondence Address: HARNESS, DICKEY & PIERCE, P.L.C., P.O. BOX 828, BLOOMFIELD HILLS, MI, 48303, US

(73) Assignee: Feinmetall GmbH, Herrenberg (DE)

(21) Appl. No.: 12/012,967

(22) Filed: Feb. 6, 2008

(30) Foreign Application Priority Data
Feb. 8, 2007 (DE) 10 2007 007 739.6
Jan. 14, 2008 (DE) 10 2008 004 792.9

(51) Int. Cl. G01R 31/28; H01L 21/68

(52) U.S. Cl. 324/758

(57) ABSTRACT

The present disclosure relates to an electrical testing device for testing electrical test samples, the electrical testing device comprising an electrical connecting device having contact surfaces for touch contacting a contact arrangement that is contactable with the test sample and to which a support device is allocated, and a middle centering device that permits only radial temperature compensation clearance using a plurality of guides for the central alignment of the support device and connecting device relative to one another.

### CROSS-REFERENCE TO RELATED APPLICATIONS

This application claims the benefit of DE 10 2007 007 739.6, filed 8 Feb., 2007 and DE 10 2008 004 792.9, filed 14 Jan. 2008. The disclosures of the above applications are incorporated herein by reference.

### FIELD

The present disclosure relates to an electrical testing device for testing electrical testing samples, preferably wafers, having an electrical connecting device that has contact surfaces for touch contacting a contact arrangement that is contactable with the test sample and to which a support device is allocated.

### BACKGROUND

The statements in this section merely provide background information related to the present disclosure and may not constitute prior art.

Electrical testing devices of the type cited in the foregoing are used to contact a test sample electrically in order to test its functionality. The electrical testing device produces electrical connectors to the test sample, that is, it contacts electrical connectings for the test sample and also makes electrical contacts available that can be connected to a testing system that supplies electrical signals to the test sample via the testing device in order to perform a functional test, for instance resistance measurements, current and voltage measurements, etc. Since the electrical test sample is frequently an extremely small component, for instance a wafer, the contact arrangement has contact elements that have extremely small dimensions and that are also arranged very close to one another. In order to make it possible to connect to the aforesaid testing system, the contact elements of the test head are in touch contact with a connecting device that converts to a greater contact interval and thus makes it possible to connect electrical connecting cables that lead to the testing system. Since during the testing there can be different room temperatures and preferably the testing is performed at different test sample temperatures in order to be able to test its function within a specific temperature range, as well, with the known electrical testing devices there is the risk that due to changes in lengths caused by thermal factors there is not always trouble-free contacting between the contact elements and the associated contact surfaces of the connecting device because of resultant positioning errors. These shifts in position result from different temperature expansion coefficients for the materials used, wherein it is necessary for structural reasons to use certain materials so that it is not possible to resolve the problem described by selecting the same material for components that work with one another. On the contrary, the aforesaid changes in length lead to mechanical stresses that can for instance warp the connecting device so that it loses its planarity, which is also needed for assured contacting, and/or so that the connecting device loses its central position due to shifts caused by temperature. Even uneven heating of individual parts of the testing device can lead to shifts in position. During touch contacting of a test sample that is to be tested, the contact elements of the contact arrangement are supported at one end on the test sample and at the other end on the associated contact surface of the electrical connecting device, so that when there is a plurality of contact elements a plurality of contact forces and thus cumulatively a high contact force acts on the connecting device. The support device is provided in order to be able to absorb this contact force without impermissible deformation of components. This is a relatively stiff component (stiffener) on which the connecting device is supported. In the known testing devices, mechanical stresses that can lead to changes in shape occur due to the different coefficients of expansion for the connecting devices and support device. The positions of the support device and connecting device relative to one another is no longer clearly fixed if the components shift due to temperatures and the associated temperature expansion coefficients. However, it is very important for the functioning of the electrical testing device that the middle/center of the support device does not shift relative to the middle/center of the connecting device and/or other components of the testing device across a broad range of temperatures.

### SUMMARY

The underlying object of the invention is therefore to provide a testing device of the type cited in the foregoing that functions perfectly within a large temperature range and permits problem-free electrical testing of the test sample.

Further areas of applicability will become apparent from the description provided herein. It should be understood that the description and specific examples are intended for purposes of illustration only and are not intended to limit the scope of the present disclosure.

This object is inventively attained using a middle centering device that permits only radial temperature compensation clearance using guides for the central alignment of the support device and connecting device relative to one another. The inventive testing device, which can be embodied in particular as a vertical testing card, thus possesses, between support device and connecting device the middle centering device, which ensures that changes in length that occur due to changes in temperature proceed only from the respective centers of the aforesaid components and in the radial direction due to the commensurately configured guides. The guides can be embodied in particular as slideways. The centers of the support device and the connecting device are diametrically opposite one another; they are disposed in particular on an equal middle normal axis, the aforesaid components. Certain functioning and certain contacting is assured because thus in accordance with the invention, although because of the different materials changes in length will occur due to changes in temperature, because of the aforesaid middle centering device in conjunction with the radial guides they are not cumulatively so great that warping occurs and/or an end face of one contacting element no longer meets the associated contact surface of the connecting device. Using the inventive procedure, due to the middle centering device in particular attaching the support device to the connecting device is performed such that the centers of both components are always disposed precisely one upon the other, even given severe fluctuations in temperature. At the same time, stresses in the assembly are avoided.

In one further development of the invention it is provided that the middle centering device is arranged outside of the contact arrangement. This embodiment permits the area of the contact arrangement to be kept free by the centering means, that is, the guides, so that the area around the respective centers of the connecting devices and contacting arrangement are available exclusively for receiving pin-like contact elements and therefore versatility for adapting to different test samples is maintained.

It is advantageous when the middle centering device has at least three guides, in particular four or more than four guides, that are arranged angularly offset to one another. These three guides are preferably angularly offset to one another by 120° or the first of the three guides with the second guide forms a 90° angle and the second guide with the third guide also forms a 90° angle, so that the third guide is offset 180° from the first guide. In this manner centering is clearly determined, that is, in the contact plane (X-Y plane) it is not possible for the center of the testing device to be in an offset position. In particular it can be provided that four guides are used that are offset from one another by 90°. A larger number of guides is also conceivable.

One further development of the invention provides that at least one of the guides is formed by a projection on the support device and/or on the connecting device and a depression that is on the connecting device and/or the support device and that receives the projection with radial clearance and with no clearance circumferentially. All of the guides are preferably embodied in this manner. The guide therefore permits displacement of the projection in the depression only in one direction, this direction being the radial direction, that is,—starting from the center of the testing device—radially outward. Running transverse to the radial direction—parallel to the testing plane—is the aforesaid circumferential direction, in which there is no clearance, so that there is no possibility of rotational offset between support device and connecting device. During the testing, in order to contact the test sample the contact arrangement and the test sample are moved perpendicular to the testing plane, that is, in the axial direction.

In particular it can be provided that the projection is embodied as a profile pin. The sectional profile of the profile pin is circular or preferably not circular but rather different from a circular shape, for instance rectangular or square, in order to assure, in conjunction with the walls of the depression, the radial guide.

The depression is embodied in particular as a through-hole, preferably as an oblong hole.

One further development of the invention provides that on its surface the projection has guide means that run parallel to the radial direction of the testing device. The guide means are in particular parallel, flat guide surfaces of the projection.

In particular, the depression can have parallel depression walls that run parallel to the radial direction of the testing device. The projection is received between the depression walls with no clearance or largely with no clearance such that it can be displaced only radially within the associated depression. The radial direction is preferably provided by an imaginary line that intersects the center axis of the testing device, the center axis, in particular the middle normal axis running through the middle/center of the support device and/or connecting device and the imaginary line extending perpendicular to the middle axis.

The connecting device can preferably be embodied as a printed circuit board. This is in particular a multi-layer printed circuit board, that is, it has conductors that are disposed in different planes of the board. The conductors lead on the one hand to the aforesaid contact surfaces that cooperate electrically with contact elements, in particular contact needles, of the contact arrangement and lead on the other hand to connectors that lead to the aforesaid testing system for instance via cable connections. Contact elements are in particular contact pins that form a contact pin arrangement. In particular spring-loaded contact pins are used, or, when the dimensions are very small, buckling beams. The contact elements are preferably borne longitudinally displaceable in the contact arrangement. The contact arrangement is preferably embodied as a contact head.

### DRAWINGS

The drawings described herein are for illustration purposes only and are not intended to limit the scope of the present disclosure in any way.

The drawings depict the inventions using an exemplary embodiment, specifically:

FIG. 1 is a schematic longitudinal section through an electrical testing device; and,

FIG. 2 is a schematic section through the testing device in FIG. 1 in the area of the slideways of a middle centering device.

### DETAILED DESCRIPTION

The following description is merely exemplary in nature and is not intended to limit the present disclosure, application, or uses. It should be understood that throughout the drawings, corresponding reference numerals indicate like or corresponding parts and features.

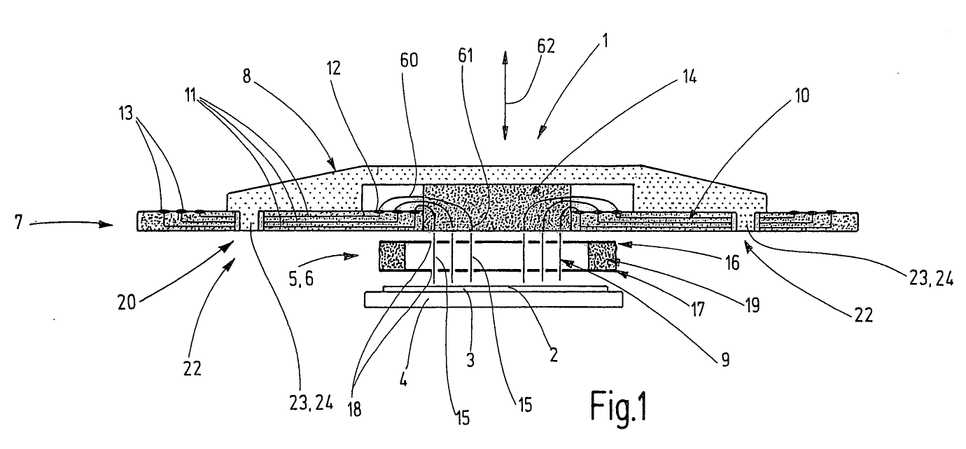

FIG. 1 is a schematic depiction of a longitudinal section through an electrical testing device 1 that is used for electrical touch contacting of an electrical test sample 2. The testing device 1 is connected by means of electrical cable connections (not shown) to a testing system (also not shown) in order to subject the test sample 2 to electrical testing. The test sample 2, which in particular can be embodied as a wafer 3, is disposed on a supporting substrate 4 that can be cooled or heated. In this manner it is possible to subject the test sample to different temperatures during the electrical testing, for instance ranging from −50° C. to +200° C., in order to test whether it works with no problems in this temperature range.

The testing device 1 is provided for touch contacting corresponding connecting points of the wafer 3.

The testing device 1 has a contact head 6 and a connecting device 7. The connecting device 7 is supported on a support device 8. The contact head 6, which can be called in general a contact arrangement 5, is provided with a plurality of contact elements 9 that are borne longitudinally displaceable and their one end areas are associated with the test sample 2 and their other end areas are associated with the connecting device 7. The connecting device 7 is embodied as a multi-layer printed circuit board 10 having conductors 11, the conductors 11 having, at their ends facing away from the contact head 6, contact surfaces 12 that lead via wire connections 60 to contact surfaces 61 that are associated with the respective contact elements 9. The contact surfaces 61 are in particular formed by the end faces of the wire connections 60. At their other, radially outwardly disposed ends the conductors 11 have electrical connector surfaces 13 that can be connected via the aforesaid cable connections (not shown) to the testing system (not shown). The arrangement is such that the connecting device 7 forms a conversion device, that is, the very small distance between the very small contact surfaces 61 (diameter 50 to 300 μm, for instance) is converted via the wire connections 60 and the conductors 11 to larger distances of the connector surfaces 13. The connector surfaces 13 each have a size that makes it possible to be able to produce contact with the cable connections (not shown) in a simple manner.

When testing the test sample 2, the testing device 1 moves toward the test sample 2 and/or the test sample 2 moves toward the testing device 1 so that the end faces of the contact elements 9 meet the wafer 3 on one hand and the contact surfaces 61 on the other hand. Contacting with no problems is possible since the contact elements 9 are embodied in particular as buckling beams 15, that is, they are slightly elastic in the axial direction due to bending. The contact head 6 has two parallel ceramic plates 16 and 17 that are disposed spaced apart from one another and that are provided with bearing bores 18 for receiving the buckling beams 15. The parallel, spaced positioning of the two ceramic plates 16 and 17 is created by means of a spacer 19.

The wire connections 60 run at least in part through a connector housing 14 that is embodied for instance as a cast block and that holds the wire connections 60 in a fixed position.

The connector housing 14 is part of the connecting device 7. The connecting device 7 is supported on the support device 8 so that the former is mechanically stabilized. This applies both for the printed circuit board 10 and for the connector housing 14.

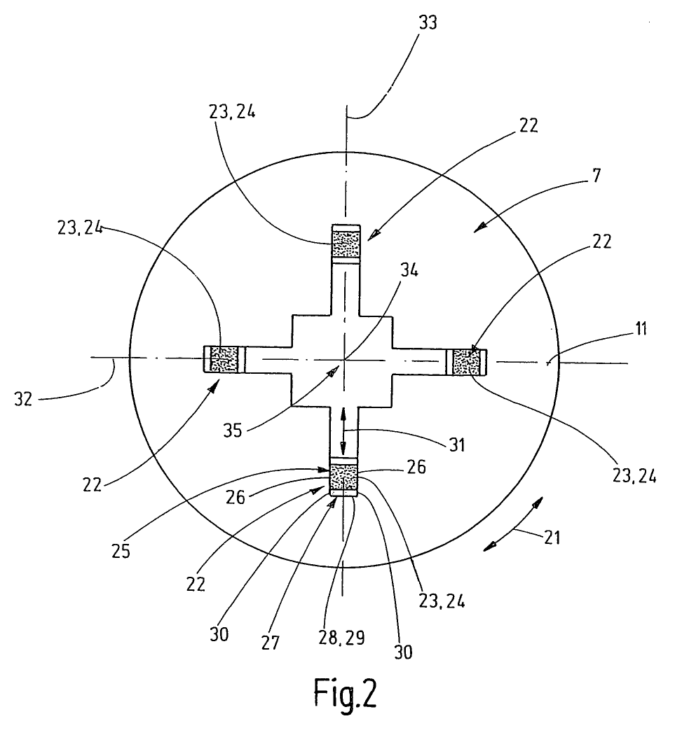

Instead of the previously known, rigid, fixed connection between the support device 8 and the connecting device 7, in accordance with the invention a middle centering device 20 is provided between the aforesaid components and, in accordance with FIGS. 1 and 2, it is formed by four guides 22, in particular slideways, that are disposed offset from one another in the circumferential direction by 90° (double arrow 21) as can be seen in particular from FIG. 2. It can be seen from FIG. 2 that the printed circuit board 11 of the connecting device 7 is embodied as a circular board.

In accordance with FIGS. 1 and 2 the slideways 22 each have a projection 23 in the form of a profile pin 24, the projections 23 being embodied in particular integral with the support device 8. The free end of the projection 23 extends in the axial direction 62. This direction is the contacting direction, that is, the direction of the relative movement that is necessary between the testing device 1 and the test sample 2 for contacting for the testing. On its surface 25 (FIG. 2) the profile pin 24 has two mutually opposing, parallel, flat guide surfaces 26. The profile pin 24 has a rectangular sectional profile. Its free end extends into a depression 27 that is embodied on the connecting device 7, the printed circuit board 10 in the present exemplary embodiment. The depression 27 is preferably configured as a through-hole 28. It has the shape of an oblong hole and thus depicts an oblong hole 29. The depression 27 has two depression walls 30 that run parallel to one another and that are spaced apart from one another such that they receive the guide surfaces 26 of the profile pin 24 largely with no clearance. The longitudinal extension of the oblong hole 29 is longer than the corresponding dimension of the profile pin 24 so that between support device 8 and connecting device 7 a relative movement can take place in the direction of the drawn-in double arrow 31, which indicates a radial direction. A radial movement is not possible transverse thereto, since this is prevented by the guidance of the guide surfaces 26 on the depression walls 30.

It is clear from FIG. 2 that the four slideways 22 are arranged such that they are disposed on two imaginary radial lines 32 and 33 that intersect one another at a 90° angle, the radial lines 32 and 33 intersecting at a mid-point 34 and the mid-point 34 forming the center 35, or the middle of the testing device 1, or forming the middle of the connecting device 7 and the middle of the support device 8. The buckling beams 15 that belong to the contact arrangement 5 are arranged about the center 35. The four slideways 22 are disposed radially outward relative to the contact arrangement 5, the longitudinal extension of the oblong holes 29 being oriented such that they are each disposed in the middle of the radial lines 32 and 33. The guide surfaces 26 of the individual profile pins 24 are configured corresponding to the orientations of the oblong holes 29.

From all of this it is clear that the component support device 8 and connecting device 7 are fixed relative to one another given material expansion or contraction caused by temperature due to the middle centering device 20 in the area of the center 35 and relative movements are only possible in the direction of the radial lines 32 and 33. This assures that the aforesaid changes in length that result from the different temperature expansion coefficients for the materials used in the components cannot lead to a situation in which offset sections occur that are so large that warping occurs and/or the end surfaces of the buckling beams 15 associated with the connector housing 14 do not meet the contact surfaces 61. The middle centering using the middle centering device 20 therefore prevents large offset sections because the changes in length that occur begin from the center and thus are symmetrical to the middle and therefore, seen from the radial direction, are only half the size as an offset that could occur if the invention is not used when buckling beams 15 that are outwardly disposed are placed centrally on the associated contact surfaces 61 so that the diametrically opposed buckling beams, which are also outwardly disposed, lead to faulty contacts due to the cumulative extensions or contractions in length. Material stresses in the associated components are also avoided due to the inventive middle centering device 20.

In the present exemplary embodiment, the support device 8 is in a cross shape. However, according to other exemplary embodiments, (not shown), it can also be provided that the support device 8 is annular or embodied as a spoked wheel.

Due to the present invention, the support device 8 is attached to the connecting device 7 such that the two centers of the two components, as already stated, are always disposed precisely one upon the other, even given severe fluctuations in temperature, so that contact is assured and the aforesaid mechanical stresses on the assembly are avoided.

In accordance with another exemplary embodiment (not shown), a kinematic reverse can also be created, that is, the depressions 27 are disposed in the support device 8 rather than in the connecting device 7. The projections 23 are then embodied as pins arranged on the connecting device 7.

Furthermore, it can be provided in all of the exemplary embodiments that the slideways 22 are configured such that positioning surfaces of the support device 8 are also embodied on the connecting device 7, in particular on the printed circuit board 10. By underlaying or using a displacement mechanism an incline in the support device 8 relative to the connecting device 7, in particular the printed circuit board 10, can be created on these positioning surfaces of the slideways 22, which form fits.

What is claimed is:

1. An electrical testing device for testing electrical testing samples, the electrical testing device comprising:
an electrical connecting device having contact surfaces for touch contacting a contact arrangement that is contactable with the test sample and to which a support device is allocated;
a middle centering device that permits only radial temperature compensation clearance using a plurality of guides for the central alignment of the support device and connecting device relative to one another.

2. The testing device in accordance with claim 1, wherein said middle centering device is arranged outside of said contact arrangement.

3. The testing device in accordance with claim 1, wherein said middle centering device has at least three guides angularly offset to one another.

4. The testing device in accordance with claim 1, wherein said middle centering device has at least four guides that are angularly offset to one another.

5. The testing device in accordance with claim 1, wherein at least one of the guides is formed by a projection on said support device and/or on said connecting device and a depression that is on said connecting device and/or said support device and that receives said projection with radial clearance and with no clearance circumferentially.

6. The testing device in accordance with claim 5, wherein said projection is a profile pin.

7. The testing device in accordance with claim 5, wherein said depression is a through-hole.

8. The testing device in accordance with claim 5, wherein said depression is an oblong hole.

9. The testing device in accordance with claim 5, wherein the projection has a guide portion that runs parallel to a radial direction of said testing device.

10. The testing device in accordance with claim 5, wherein said depression includes parallel depression walls that run parallel to a radial direction of said testing device.

11. The testing device in accordance with claim 9, wherein the radial direction is defined by an imaginary line that intersects a middle axis of the testing device, said middle axis running through a middle/center of said support device and/or said connecting device and said imaginary line running perpendicular to the middle axis.

12. The testing device in accordance with claim 10, wherein the radial direction is defined by an imaginary line that intersects a middle axis of the testing device, said middle axis running through a middle/center of said support device and/or said connecting device and said imaginary line running perpendicular to the middle axis.

13. The testing device in accordance with claim 1, wherein said connecting device is a printed circuit board.

14. The testing device in accordance with claim 1, wherein said contact arrangement is embodied as a contact head that has a contact pin arrangement with pin-like contact elements.

15. The testing device in accordance with claim 1, wherein said contact elements are buckling beams that are longitudinally displaceable.

16. The testing device in accordance with claim 1, wherein said guides are slideways.
